(19) United States
(12) Patent Application Publication
(10) Pub. No.: US 2009/0075420 A1
(43) Pub. Date: Mar. 19, 2009

(54) METHOD OF FORMING CHALCOGENIDE LAYER INCLUDING TE AND METHOD OF FABRICATING PHASE-CHANGE MEMORY DEVICE

(75) Inventors: Byoung-jae BAE, Hwaseong-si (KR); Sung-lae CHO, Yongin-si (KR); Jin-Il LEE, Seongnam-si (KR); Ju-hyung SEO, Hwaseong-si (KR); Hye-young PARK, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/212,773

(22) Filed: Sep. 18, 2008

(30) Foreign Application Priority Data
Sep. 18, 2007 (KR) 10-2007-0094777

(51) Int. Cl. H01L 45/00

(52) U.S. Cl. 438/102; 257/E45.002

(57) ABSTRACT

The method of forming a Te-containing chalcogenide layer includes radicalizing a first source that contains Te to form a radicalized Te source, and forming a Te-containing chalcogenide layer by supplying the radicalized Te source into a reaction chamber. A method fabricating a phase change memory device includes loading a substrate on which a lower electrode is formed into a reaction chamber, radicalizing a first source that contains Te to form a radicalized Te source, forming a phase change material film containing Te on the lower electrode by supplying the radicalized Te source into the reaction chamber, and forming an upper electrode on the phase change material film.

### PRIORITY CLAIM

A claim of priority is made to Korean Patent Application No. 10-2007-0094777, filed Sep. 18, 2007, in the Korean Intellectual Property Office, the disclosure of which is incorporated herein in its entirety by reference.

### SUMMARY

The present invention generally relates to the formation of a chalcogenide layer which includes tellurium (Te). Such a layer may be used, for example, in the fabrication of a phase-change memory device.

Chalcogenide is responsive to temperature conditions to as to be stably transformed between crystalline and amorphous states. The crystalline state has a lower specific resistance than the amorphous state, and this phase change property can be utilized to store data. A phase change random access memory (PRAM) is one example of a memory device which utilizes the phase change characteristics of chalcogenide to store data.

Each unit memory cell of a PRAM generally includes an access device and a phase change resistor which may, for example, be electrically connected between a bit line and a word line of the PRAM. The phase change resistor is a variable resistor and generally includes a phase change material film disposed between a lower electrode and an upper electrode. Typically, the access device is electrically connected to the lower electrode.

FIG. 1 illustrates temperature conditions applied to the phase change resistor during “set” and “reset” programming operations. Set programming refers to the process of placing the phase change resistor in its crystalline state, whereas reset programming refers to placing the phase change resistor in its amorphous state. It should be noted that the terms “crystalline state” and “amorphous state” are relative terms. That is, the phase change resistor need not be fully crystalline in the crystalline state, and the phase change resistor need not be fully amorphous in the amorphous state.

As shown in FIG. 1, set programming entails heating of the phase change material of the phase change resistor at a temperature which falls between a crystallization temperature Tx and a melting point temperature Tm, followed by cooling. Reset programming entails heating the phase change material to the melting point temperature Tm, also followed by cooling. As shown in the figure, the reset programming heat treatment is carried out for a relative short period of time when compared to that of the set programming. Also, the cooling rate in the reset programming may be more rapid than that of the set programming.

The heat treatment itself is achieved by controlling a write current through the phase change resistor to create joule heating conditions which result in temperature profiles that mirror those illustrated in FIG. 1. As a write current flows through the lower electrode and the switching device of the unit memory cell, joule heat is generated at a boundary surface between the lower electrode and the phase change material film. The joule heating induced temperature of the phase change material film is dependent upon the magnitude and duration of the write current.

As mentioned above, the present invention generally relates to the formation of a chalcogenide layer which includes tellurium (Te), which may, for example, be utilized at a phase change material layer of a phase change resistor.

According to an aspect of the present invention, a method of forming a Te-containing chalcogenide layer is provided. The method includes radicalizing a first source that contains Te to form a radicalized Te source, and forming a Te-containing chalcogenide layer by supplying the radicalized Te source into a reaction chamber.

According to another aspect of the present invention, a method of fabricating a phase change memory device is provided. The method includes loading a substrate on which a lower electrode is formed into a reaction chamber, radicalizing a first source that contains Te to form a radicalized Te source, forming a phase change material film containing Te on the lower electrode by supplying the radicalized Te source into the reaction chamber, and forming an upper electrode on the phase change material film.

### BRIEF DESCRIPTION OF THE DRAWINGS

The above and other aspects and features of the present invention will become readily apparent from the detailed description that follows, with reference to the accompanying drawings, in which:

FIG. 1 illustrates temperature characteristics during set and reset programming of a phase change resistor;

FIG. 2 is a flow chart illustrating a method of forming a Te-containing chalcogenide layer according to an embodiment of the present invention;

FIG. 3 is a gas pulsing diagram for forming a Ge—Sb—Te film using a chemical vapor deposition (CVD) method according to an embodiment of the present invention;

FIG. 4 is a gas pulsing diagram for forming a Ge—Sb—Te film using an atomic layer deposition (ALD) method according to an embodiment of the present invention;

FIGS. 5A and 5B are cross-sectional views for use in explaining a method of fabricating a phase change memory device according to an embodiment of the present invention;

FIGS. 6A through 6C are cross-sectional views for use in explaining a method of fabricating a phase change memory device according to another embodiment of the present invention; and

FIGS. 7 and 8 are respective photographic images of Te-containing chalcogenide layers formed according to a fabrication example and a comparative example.

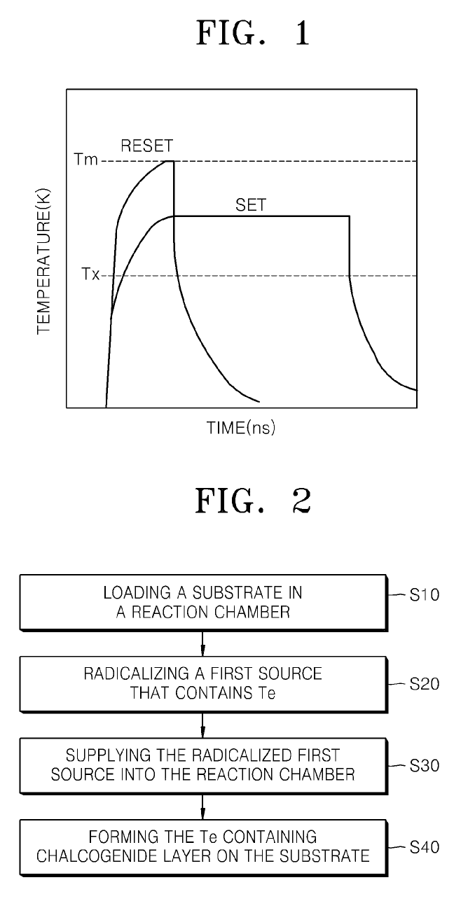

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided to present a thorough and complete disclosure, and to fully convey concepts of the invention to those skilled in the art. In the drawings, the relative thicknesses of layers and regions are not necessarily drawn to scale and are exaggerated for clarity. To avoid redundancy in the disclosure, like reference numerals denote the same or similar elements throughout the drawings.

FIG. 2 is a flow chart of a method of forming a Te-containing chalcogenide layer according to an embodiment of the present invention.

Referring to FIG. 2, a substrate is loaded into a reaction chamber (S10). The substrate may include a semiconductor material or film at a surface thereof. Examples of the semiconductor material or film include Si and/or SiC. In addition, or alternatively, the substrate may include a dielectric and/or conductive material or film at a surface thereof. Examples of the dielectric material or film include silicon oxide, titanium oxide, aluminum oxide (Al₂O₃), zirconium oxide, and/or hafnium oxide. Examples of the conductive material or film include Ti, TiN, Al, Ta, TaN, and/or TiAlN.

The reaction chamber may, for example, be a cold wall type reaction chamber or a hot wall type reaction chamber. Generally, a cold wall type reaction chamber is capable of processing a single substrate at a time, and includes a substrate stage having heating wires and a shower head located on the substrate stage. On the other hand, the hot wall type reaction chamber includes heating wires in a wall thereof, such that multiple substrates can be vertically stacked within the chamber and batched processed at the same time. In any event, the embodiment is not limited to any particular type of reaction chamber.

Referring again to FIG. 2, a first source that contains Te is radicalized to form a radicalized first source (S20). For example, the Te containing first source, that is, a Te source may be expressed either or both of Chemical Equations 1 and 2 below:

R₁—Te—R₂ Chemical Equation 1

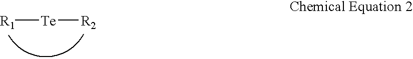

where R₁ and R₂ are independently at least one of C1-C0 alkyl group, a C2-C12 olefinic group, a C2-C13 acetylenic group, an allenic group (—CHCCH₂), a cyan group (—CN), an —NCX group (where X is O, S, Se, or Te), an azide ligand (N₃), an amide ligand (NR₃R₄, where R₃ and R₄ are independently a C1-10 alkyl group, a C2-C12 olefinic group, a C2-C13 acetylenic group, or an allenic group).

In the preceding paragraph, the word “independently” means that R₁ and R₂ can be the same as each other or different from each other, and that R₃ and R₄ can be the same as each other or different from each other.

In contrast to Chemical Equation 1, Chemical Equation 2 represents a structure in which R₁ and R₂ are chemically bonded to each other to form a ring system.

The first source may be radicalized by preheating the Te source prior to being supplied to the reaction chamber. In other words, a Te—R radical may be generated according to Reaction Scheme 1 (below) by heating the Te source prior to supplying the same to the reaction chamber. The preheating temperature for generating the Te—R radical may, for example, be between about 150° C. and about 400° C. If the preheating temperature is below 150° C., the Te—R radical may not be generated, and if the temperature exceeds 400° C., decomposition of the Te—R radical may result.

R—Te—R→R—Te.+.R Reaction Scheme 1

For example, in the case where a cold wall type reaction chamber is utilized, the Te source can be radicalized by preheating the Te source before the radicalized source is supplied through the shower head. In the case of a hot wall type reaction chamber is utilized, a Te source supply tube through which the Te source is supplied may be installed on an inner wall of the reaction chamber. In this case, the Te source supplied through the Te source supply tube may be radicalized by being heated simultaneously as the reaction chamber is heated. Alternatively, for example, the Te source may be radicalized by vaporization at a particular temperature prior to being supplied to the reaction chamber.

Referring once again to FIG. 2, the radicalized Te source is supplied into the reaction chamber (S30), and then, a Te-containing chalcogenide layer is formed on the substrate (S40).

A second source may be further supplied to the reaction chamber before, after, and/or at the same time the radicalized Te source is supplied into the reaction chamber. In this case, by supplying the radicalized Te source into the reaction chamber, a deposition temperature of the Te-containing chalcogenide layer can be reduced. This is because reactivity (or telluridation power) between the Te source and the second source increases by supplying the radicalized Te source into the reaction chamber. As an example, the deposition temperature of the Te-containing chalcogenide layer may be reduced to a range of 200° C. to 300° C. A Te-containing chalcogenide layer deposited at such a low process temperature may exhibit a smaller grain size than a Te-containing chalcogenide layer formed at a higher process temperature. This may result in enhanced step coverage of the Te-containing chalcogenide layer, thus allowing a conformal Te-containing chalcogenide layer to be formed on a sidewall of the via hole without blocking an inlet of the via hole. In this manner, the via hole can be filled with the Te-containing chalcogenide without voids.

The second source may, for example, be one or more of a Ge source, an Sb source, a Bi source, an As source, a Sn source, an O source, a Au source, a Pd source, a Se source, a Ti source, and a S source. Depending on the make-up of the second source, the Te-containing chalcogenide layer may be a Ge—Sb—Te film, a Ge—Te film, a Sb—Te film, a Ge—Bi—Te film, a Ge—Te—As film, a Ge—Te—Sn film, a Ge—Te—Sn—O film, a Ge—Te—Sn—Au film, a Ge—Te—Sn—Pd film, a Ge—Te—Se film, a Ge—Te—Ti film, a (Ge, Sn)—Sb—Te film, a Ge—Sb—(Se, Te) film, or a Ge—Sb—Te—S film. That is, the Te-containing chalcogenide layer may include one or more of N, O, Bi, Sn, B and Si as an impurity.

For example, in the case where the second sources is a Ge source and/or a Sb source, the resultant Te-containing chalcogenide layer formed on the substrate may be a Ge—Sb—Te film, a Ge—Te film, or a Sb—Te film.

Examples of the Ge source include one or more of Ge(CH₃)₄, Ge(C₂H₅)₄, Ge(n-C₄H₉)₄, Ge(i-C₄H₉)₄, Ge(C₆H₅)₄, Ge(CH₂═CH)₄, Ge(CH₂CH═CH₂)₄, Ge(CF₂═CF)₄, Ge(C₆H₅CH₂CH₂CH₂)₄, Ge(CH₃)₃(C₆H₅), Ge(CH₃)₃(C₆H₅CH₂), Ge(CH₃)₂(C₂H₅)₂, Ge(CH₃)₂(C₆H₅)₂, GeCH₃(C₂H₅)₃, Ge(CH₃)₃(CH═CH₂), Ge(CH₃)₃(CH₂CH═CH₂), Ge(C₂H₅)₃(CH₂CH═CH₂), Ge(C₂H₅)₃(C₅H₅), GeH(CH₃)₃, GeH(C₂H₅)₃, GeH(C₃H₇)₃, Ge(N(CH₃)₂)₄, Ge(N(CH₃)(C₂H₅))₄, Ge(N(C₂H₅)₂)₄, Ge(N(i-C₃H₇)₂)₄, Ge[N(Si(CH₃)₃)₂]₄.

Examples of the Sb source include one or more of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, Sb[N(Si(CH₃)₃)₂]₃.

The Te-containing chalcogenide layer can be formed, for example, by using a chemical vapor deposition (CVD) method or an atomic layer deposition (ALD) method.

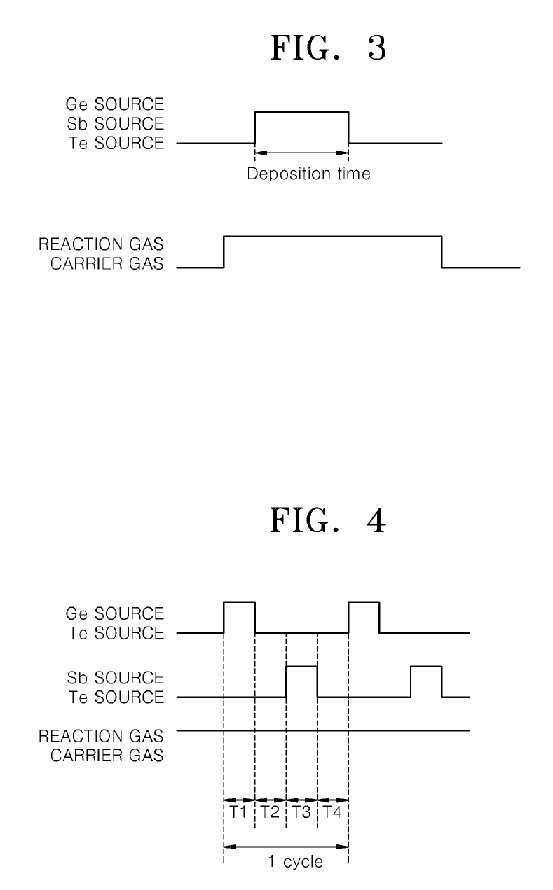

FIG. 3 is an example of a gas pulsing diagram in the case where a Ge—Sb—Te film is formed using a CVD method.

Referring to FIG. 3, the Ge—Sb—Te film may be formed by simultaneously supplying a Ge source, a Sb source, and a radicalized Te source into a reaction chamber while a carrier gas and a reaction gas are also supplied to the reaction chamber. The carrier gas may, for example, be an inert gas such as Ar, He, or N₂, and the reaction gas may, for example, be H₂, O₂, O₃, H₂O, SiH₄, B₂H₆, N₂H₄, or NH₃. As discussed above, the radicalized Te source can be formed by preheating a Te source prior to being supplied to the reaction chamber. As examples, the Ge source, the Sb source, and the Te source may be injected at a flow rate of 10 sccm to 1000 sccm for 1 to 1000 seconds.

FIG. 4 is an example of a gas pulsing diagram in the case where a Ge—Sb—Te film is formed using an ALD method.

Referring to FIG. 4, a Ge—Te film is formed by injecting the Ge source and the radicalized Te source for time period T₁ into a reaction chamber while a carrier gas and a reaction gas are supplied to the reaction chamber. The carrier gas may, for example, be an inert gas such as Ar, He, or N₂, and the reaction gas may, for example, be H₂, O₂, O₃, H₂O, SiH₄, B₂H₆, N₂H₄, or NH₃. The supply of the Ge and radicalized Te sources is stopped for a time period T₂, during which time physically adsorbed Ge sources and Te sources and unreacted Ge sources and Te sources may be removed by the supply of the inert gas and the reaction gas into the reaction chamber. A Sb—Te film is formed by supplying a Sb source and a radicalized Te source into the reaction chamber for a time period T₃. The supply of the sources is stopped for a time period T₄, during which time physically adsorbed Sb sources and Te sources and unreacted Sb sources and Te sources are removed by the supply of the inert gas and the reaction gas into the reaction chamber. Time periods T1˜T4 constitute a an ALD unit cycle, and the Ge—Sb—Te film can be formed by repetition of multiple ALD unit cycles. As examples, the Ge source, the Sb source, and the radicalized Te source may be injected at a flow rate of about 10 sccm to about 1000 sccm for about 0.1 to about 60 seconds.

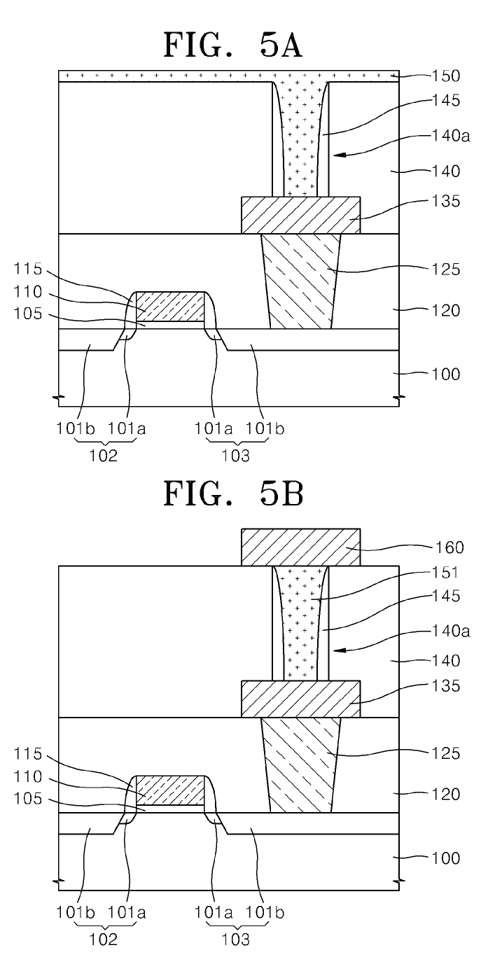

FIGS. 5A and 5B are cross-sectional views for use in explaining methods of fabricating a phase change memory device according to an embodiment of the present invention.

Referring to FIG. 5A, an active region is defined by forming a device isolation film (not shown) on a substrate 100. After sequentially forming a gate insulating film 105 and a gate conductive film on the active region, a gate electrode 110 is formed by sequentially etching the gate conductive film and the gate insulating film 105. Low concentration dopant regions 101a are formed in the substrate 100 adjacent to the gate electrode 110 by doping with a dopant at a low concentration in the substrate 100 using the gate electrode 110 as a mask.

A gate spacer insulating film is stacked on the substrate 100 in which the low concentration dopant regions 101a are formed, and gate spacers 115 are formed on sidewalls of the gate electrode 110 by anisotropically etching the gate spacer insulating film. Thereafter, high concentration dopant regions 101b are formed in the substrate 100 adjacent to the gate spacers 115 by doping with a dopant at a high concentration in the substrate 100 using the gate electrode 110 and the gate spacers 115 as masks.

The low concentration dopant regions 101a and the high concentration dopant regions 101b form source regions and drain regions. More specifically, a pair of the low concentration dopant region 101a and the high concentration dopant region 101b located on a side of the gate electrode 110 forms a source region 102, and a pair of the low concentration dopant region 101a and the high concentration dopant region 101b located on the other side of the gate electrode 110 forms a drain region 103. The gate electrode 110, the source region 102, and the drain region 103 constitute an MOS transistor which functions as an access device. However, the access device is not limited to an MOS transistor, and may instead, for example, be implemented by a diode or a bipolar transistor.

A first interlayer insulating layer 120 is formed on the substrate 100 in which the source and drain regions 102 and 103 are formed, and a contact plug 125 that contacts the drain region 103 is formed in the first interlayer insulating layer 120 through the first interlayer insulating layer 120. The contact plug 125 may, for example, be formed of a tungsten film.

A lower electrode 135 covering the contact plug 125 may be formed on the contact plug 125. Examples of a material of the lower electrode 135 include TiN, TiAlN, TaN, WN, MoN, NbN, TiSiN, TiBN, ZrSiN, WSiN, WBN, ZrAlN, MoAlN, TaSiN, TaAlN, TiW, TiAl, TiON, TiAlON, WON, and TaON.

A mold insulating film 140 is formed on the lower electrode 135, and a via hole 140a that exposes a portion of the lower electrode 135 is formed in the mold insulating film 140. A hole spacer insulating film is stacked on the substrate 100 in which the via hole 140a is formed, and the lower electrode 135 is exposed in the via hole 140a by anisotropically etching the hole spacer insulating film. As a result, a hole spacer 145 is formed on an inner sidewall of the via hole 140a. In this manner, an effective diameter of the via hole 140a may be smaller than a resolution limit of a photolithography process.

Next, a phase change material film 150 is stacked on the substrate 100 on which the via hole 140a is formed. In this embodiment, the phase change material film 150 is a Te-containing chalcogenide layer, and is formed using the method described above with reference to FIG. 2. Thus, the deposition temperature of the phase change material film 150 can be reduced to a range of about 200° C. to about 300° C. The resultant smaller grain size allows the phase change material film 150 to stably fill the small-diameter via hole 140a without voids.

Referring to FIG. 5B, a phase change material pattern 151 is formed by planarizing the phase change material film 150, and an upper electrode 160 is formed on the phase change material pattern 151. The planarizing of the phase change material film 150 can be achieved, for example, using an etch back process or by chemical mechanical polishing (CMP). As a result, a phase change resistor 151 that includes the lower electrode 135, the upper electrode 160, and the phase change material pattern 151 disposed between the lower electrode 135 and the upper electrode 160 is formed.

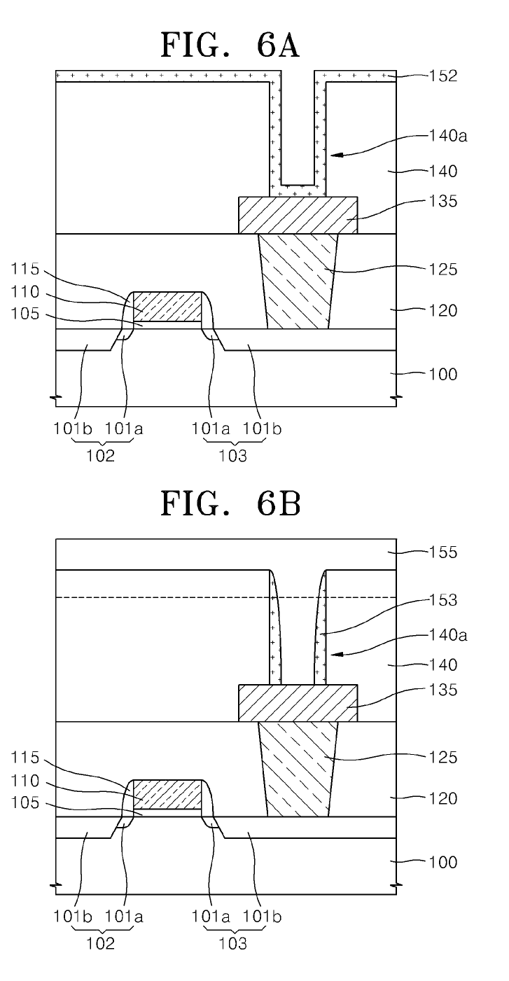

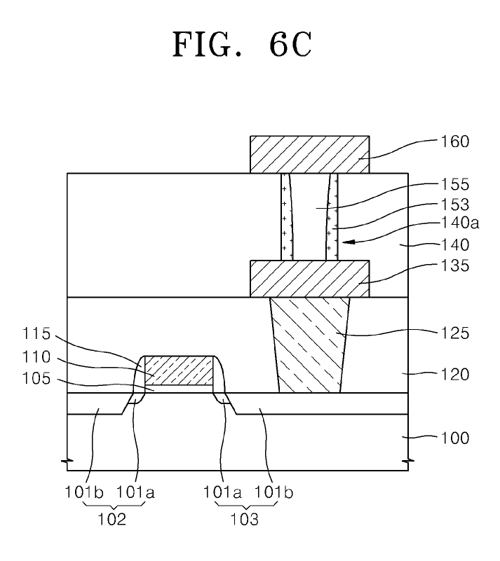

FIGS. 6A, 6B, and 6C are cross-sectional views for use in describing a method of fabricating a phase change memory device according to another embodiment of the present invention. To avoid redundancy in the description, only those aspects of the current embodiment which differ from the embodiment of FIGS. 5A and 5B are discussed below.

Referring to FIG. 6A, a mold insulating film 140 is formed on a lower electrode 135, and a via hole 140a that exposes a portion of the lower electrode 135 is formed in the mold insulating film 140. A phase change material film 152 is stacked in the via hole 140a. The phase change material film 152 is formed so as to not completely fill the via hole 140a, and instead to conformally cover sidewalls of the via hole 140a. In this embodiment, the phase change material film 152 is a Te-containing chalcogenide layer that is formed using the method described above with reference to FIG. 2. Thus, relatively small grain size of the Te-containing chalcogenide layer allows the phase change material film 152 the conformally cover the sidewalls of the via hole 140a without blocking an upper portion of the via hole 140a.

Referring to FIG. 6B, an upper surface of the mold insulating film 140 is exposed simultaneously forming a phase change material spacer 153 on sidewalls of the via hole 140a by anisotropically etching the phase change material film 152 until the lower electrode 135 is exposed. A buffer insulating film 155 is stacked on the exposed lower electrode 135 and the mold insulating film 140 until the via hole 140a is filled. Sidewalls of the buffer insulating film 155 in the via hole 140a are surrounded by the phase change material spacer 153.

An upper surface of the phase change material spacer 153 is exposed by planarizing the substrate 100 on which the buffer insulating film 155 is formed. As an example, the planarizing can be performed until reaching the dashed-line shown in FIG. 6B.

Referring to FIG. 6C, an upper electrode 160 is formed on the substrate 100 in which the upper surface of the phase change material spacer 153 is exposed. As a result, a phase change resistor that includes the lower electrode 135, the upper electrode 160, and the phase change material spacer 153 disposed between the lower electrode 135 and the upper electrode 160 is formed. A contact area between the phase change material spacer 153 and the lower electrode 135 can be smaller than that in the phase change material pattern 151 described with reference to FIG. 5B. Thus, the effective current density of a writing current applied to the phase change material spacer 153 can further be increased.

Described next are a number of different fabrication examples which are in accordance with one or more embodiments of the present invention, and a number of comparative examples.

### FABRICATION EXAMPLE 1

A substrate was loaded onto a reaction chamber. Ar with a flow rate of 500 sccm and H₂ with a flow rate of 100 sccm were supplied to the reaction chamber. After heating Te(C(CH₃)₃)₂ with a flow rate of 100 sccm to a temperature of 200° C., the heated Te(C(CH₃)₃)₂ was supplied to the reaction chamber to which Ar and H₂ are being supplied. At the same time, Sb(N(CH₃)₂)₃ was supplied with a flow rate of 100 sccm to form a Sb₂Te₃ film. The duration of supplying Sb(N(CH₃)₂)₃ and the heated Te(C(CH₃)₃)₂ to 200° C. was 900 seconds. The heater was set at a temperature of 200° C. in the reaction chamber.

### FABRICATION EXAMPLE 2

A Sb₂Te₃ film was formed using the same method described in the Fabrication example 1 except as follows. That is, Te(C(CH₃)₃)₂ was heated to a temperature of 225° C., and the duration of supplying Sb(N(CH₃)₂)₃ and the Te(C(CH₃)₃)₂ heated to 225° C. was 600 seconds. The heater was set at a temperature of 225° C. in the reaction chamber.

### FABRICATION EXAMPLE 3

A Sb₂Te₃ film was formed using the same method described in the Fabrication example 1 except as follows. That is, Te(C(CH₃)₃)₂ was heated to a temperature of 250° C., and the duration of supplying Sb(N(CH₃)₂)₃ and the Te(C(CH₃)₃)₂ heated to 250° C. was 600 seconds. The heater was set at a temperature of 250° C. in the reaction chamber.

### FABRICATION EXAMPLE 4

A Sb₂Te₃ film was formed using the same method described in the Fabrication example 1 except as follows. That is, Te(C(CH₃)₃)₂ was heated to a temperature of 275° C., and the duration of supplying Sb(N(CH₃)₂)₃ and the Te(C(CH₃)₃)₂ heated to 275° C. was 600 seconds. The heater was set at a temperature of 275° C. in the reaction chamber.

### COMPARATIVE EXAMPLE 1

A Sb₂Te₃ film was formed using the same method described in the Fabrication example 1 except as follows. That is, Te(C(CH₃)₃)₂ was heated to a temperature of 120° C., and the duration of supplying Sb(N(CH₃)₂)₃ and the Te(C(CH₃)₃)₂ heated to 120° C. was 90 seconds. The heater was set at a temperature of 280° C. in the reaction chamber.

### COMPARATIVE EXAMPLE 2

A Sb₂Te₃ film was formed using the same method described in the Fabrication example 1 as follows. That is, Te(C(CH₃)₃)₂ was heated to a temperature of 120° C., and the duration of supplying Sb(N(CH₃)₂)₃ and the Te(C(CH₃)₃)₂ heated to 120° C. was 90 seconds. The heater was set at a temperature of 300° C. in the reaction chamber.

### COMPARATIVE EXAMPLE 3

A Sb₂Te₃ film was formed using the same method described in the Fabrication example 1 except as follows. That is, Te(C(CH₃)₃)₂ was heated to a temperature of 120° C., and the duration of supplying Sb(N(CH₃)₂)₃ and the Te(C(CH₃)₃)₂ heated to 120° C. was 90 seconds. The heater was set at a temperature of 330° C. in the reaction chamber.

### COMPARATIVE EXAMPLE 4

A Sb₂Te₃ film was formed using the same method described in the Fabrication example 1 except as follows. That is, Te(C(CH₃)₃)₂ was heated to a temperature of 120° C., and the duration of supplying Sb(N(CH₃)₂)₃ and the Te(C(CH₃)₃)₂ heated to 120° C. was 90 seconds. The heater was set at a temperature of 350° C. in the reaction chamber.

Table 1 summarizes the experimental condition, deposition thickness, and deposition rate of each of the Sb₂Te₃ films of the Fabrication examples 1 through 4 and the Comparative examples 1 through 4.

TABLE 1

| | | Set | | |
|---|---|---|---|---|
| | Preheat | temperature | | |
| | temperature | of heater | Deposition | Deposition |
| | for Te | in reaction | thickness of | rate of |
| | source | chamber | Sb₂Te₃ | Sb₂Te₃ |
| Fabrication | 200° C. | 200° C. | 60 Å/900 sec | 0.06 Å/sec |
| example 1 | | | | |
| Fabrication | 225° C. | 225° C. | 250 Å/600 sec | 0.42 Å/sec |
| example 2 | | | | |
| Fabrication | 250° C. | 250° C. | 370 Å/600 sec | 0.62 Å/sec |
| example 3 | | | | |
| Fabrication | 275° C. | 275° C. | 780 Å/600 sec | 1.3 Å/sec |
| example 4 | | | | |
| Comparative | 120° C. | 280° C. | No deposition | 0 |
| example 1 | | | | |
| Comparative | | 300° C. | 200 Å/90 sec | 2.2 Å/sec |
| example 2 | | | | |
| Comparative | | 330° C. | 320 Å/90 sec | 3.6 Å/sec |
| example 3 | | | | |
| Comparative | | 350° C. | 520 Å/90 sec | 5.8 Å/sec |
| example 4 | | | | |

Referring to Table 1, in the cases where the Te source that is preheated at a temperature of 200° C. or above is supplied to the reaction chamber (Fabrication examples 1 through 4), it is seen that the Sb₂Te₃ film can be deposited at a temperature of less than 300° C., and furthermore, even at a temperature as low as 200° C. However, in the cases where the Te source that is preheated at a temperature of 120° C. (Comparative examples 1 through 4), the Sb₂Te₃ film can be only deposited at a temperature of 300° C. or above.

As described above, the deposition temperature of the Te-containing chalcogenide layer can be reduced by approximately 100° C. by heating the Te source at a temperature of 150° C. or above to thereby radicalize the Te source. The lower deposition temperature may result from increased reactivity between the radicalized Te source and the Sb source.

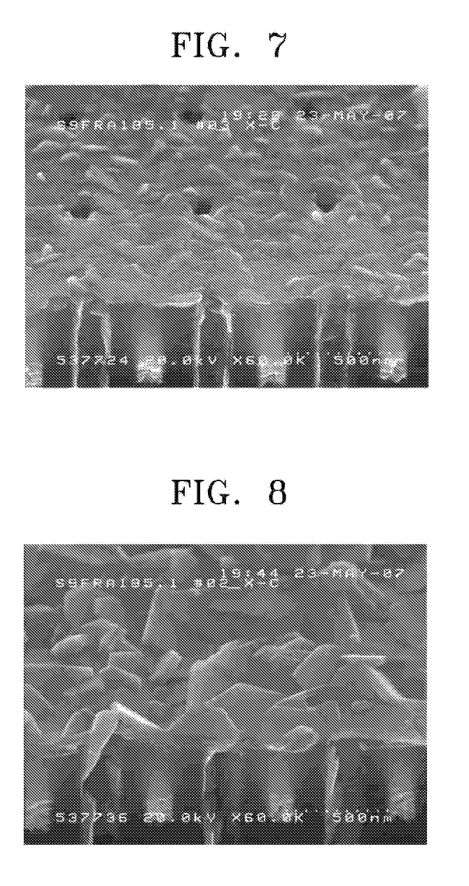

FIGS. 7 and 8 are photo images of the Te-containing chalcogenide layer formed according to the Fabrication example 2 and the Comparative example 2, respectively.

Referring to FIGS. 7 and 8, it is seen that the Te-containing chalcogenide layer formed according to the Fabrication example 2 (FIG. 7) has a smaller grain size than that of the Te-containing chalcogenide layer formed according to the Comparative example 2 (FIG. 8).

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a Te-containing chalcogenide layer, comprising:
radicalizing a first source that contains Te to form a radicalized Te source; and
forming a Te-containing chalcogenide layer by supplying the radicalized Te source into a reaction chamber.

2. The method of claim 1, wherein the first source is chemically expressed by at least one of Formulae 1 and 2:
R₁—Te—R₂ Formula 1 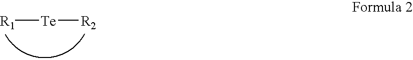
where R₁ and R₂ are independently at least one of a C1-C10 alkyl group, a C2-C12 olefinic group, a C2-C13 acetylenic group, an allenic group (—CHCCH₂), a cyan group (—CN), an —NCX group (where X is O, S, Se, or Te), an azide ligand (N₃), an amide ligand (NR₃R₄, where R₃ and R₄ are independently are an C1-C10 alkyl group, a C2-C12 olefinic group, a C2-C13 acetylenic group, or an allenic group).

3. The method of claim 1, wherein radicalizing the first source comprises heating the first source.

4. The method of claim 3, wherein heating the first source comprises passing the first source through a preheater before the radicalized Te source is supplied to the reaction chamber.

5. The method of claim 3, wherein a first source supply tube through which the first source is supplied is installed on an inner wall of the reaction chamber, and wherein the heating the first source comprises heating the first source simultaneously as the reaction chamber is heated.

6. The method of claim 3, wherein heating the first source comprises vaporizing the first source.

7. The method of claim 1, wherein forming the Te-containing chalcogenide layer is performed at a temperature between about 200° C. and about 300° C.

8. The method of claim 1, further comprising supplying a second source into the reaction chamber.

9. The method of claim 8, wherein the second source is at least one selected from the group consisting of a Ge source, an Sb source, a Bi source, an As source, a Sn source, an O source, a Au source, a Pd source, a Se source, a Ti source, and a S source.

10. The method of claim 8, wherein the Te-containing chalcogenide layer is formed of Ge—Sb—Te, Ge—Bi—Te, Ge—Te—As, Ge—Te—Sn, Ge—Te, Ge—Te—Sn—O, Ge—Te—Sn—Au, Ge—Te—Sn—Pd, Ge—Te—Se, Ge—Te—Ti, (Ge, Sn)—Sb—Te, Ge—Sb—(Se, Te), or Ge—Sb—Te—S.

11. The method of claim 1, wherein the radicalized Te source is supplied to the reaction chamber together with a carrier gas.

12. The method of claim 1, wherein the radicalized Te source is supplied to the reaction chamber together with a carrier gas and a reaction gas.

13. The method of claim 1, further comprising purging physically adsorbed Te source and unreacted Te source by supplying an inert gas and a reaction gas into the reaction chamber after supplying the radicalized Te source into the reaction chamber.

14. A method of fabricating a phase change memory device comprising:
loading a substrate on which a lower electrode is formed into a reaction chamber;
radicalizing a first source that contains Te to form a radicalized Te source;
forming a phase change material film containing Te on the lower electrode by supplying the radicalized Te source into the reaction chamber; and
forming an upper electrode on the phase change material film.

15. The method of claim 14, wherein the first source is chemically expressed by at least one of Formulae 1 and 2:
R₁—Te—R₂ Formula 1 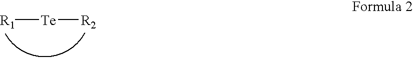
where R₁ and R₂ are independently at least one of a C1-C10 alkyl group, a C2-C12 olefinic group, a C2-C13 acetylenic group, an allenic group (—CHCCH₂), a cyan group (—CN), an —NCX group (where X is O, S, Se, or Te), an azide ligand (N₃), an amide ligand (NR₃R₄, where R₃ and R₄ are independently are an C1-C10 alkyl group, a C2-C12 olefinic group, a C2-C13 acetylenic group, or an allenic group).

16. The method of claim 14, further comprising forming a mold insulating film including a via hole that exposes a portion of the lower electrode before forming the phase change material film,
wherein the phase change material film is formed in the via hole.

17. The method of claim 14, wherein radicalizing the first source comprises heating the first source.

18. The method of claim 14, wherein forming the phase change material film containing Te is performed at a temperature between about 200° C. and about 300° C.

19. The method of claim 14, further comprising supplying a second source into the reaction chamber.

20. The method of claim 19, wherein the second source is at least one selected from the group consisting of a Ge source, an Sb source, a Bi source, an As source, a Sn source, an O source, a Au source, a Pd source, a Se source, a Ti source, and a S source.
